(19) United States
(12) Patent Application Publication
(10) Pub. No.: US 2010/0073011 A1
(43) Pub. Date: Mar. 25, 2010

(54) LIGHT SOAKING SYSTEM AND TEST METHOD FOR SOLAR CELLS

(75) Inventors: Vicky Svidenko, San Jose, CA (US); Rinat Shimshi, San Jose, CA (US); Yuqiang Li, Xi'an (CN)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/564,697

(22) Filed: Sep. 22, 2009

Related U.S. Application Data
(60) Provisional application No. 61/099,531, filed on Sep. 23, 2008.

(30) Foreign Application Priority Data
Sep. 21, 2009 (CN) 200910175668.9

(51) Int. Cl. G01R 31/02; G01N 17/00

(52) U.S. Cl. 324/537; 73/865.6

(57) ABSTRACT

A method and apparatus for exposing a solar device to simulated environmental conditions is described. In one embodiment, a chamber is described. The chamber includes a frame defining a partial enclosure having an interior volume, the frame comprising a door selectively sealing an opening in the frame, a plurality of lighting devices coupled to the enclosure interior of an open wall, each of the plurality of lighting devices being positioned to direct light toward an upper surface of a platen disposed in the interior area, and a plurality of fan units positioned in an opening formed in a sidewall of the frame, each of the plurality of fan units positioned to direct ambient air flow from the outside of the enclosure toward the platen and between the plurality of lighting devices to exit through the open wall.

### CROSS-REFERENCE TO RELATED APPLICATIONS

This application claims benefit of U.S. Provisional Patent Application Ser. No. 61/099,531, filed Sep. 23, 2008, and Chinese Patent Application Serial No. ______, filed Sep. 21, 2009, under the same title, both of which applications are herein incorporated by reference.

### BACKGROUND OF THE INVENTION

Embodiments of the present invention generally relate to apparatus and processes for testing and/or qualifying a solar device.

### DESCRIPTION OF THE RELATED ART

Photovoltaic (PV) devices or solar cells are devices which convert sunlight into direct current (DC) electrical power. Typical thin film PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect. Solar cells may be tiled into larger solar arrays. The solar arrays are created by connecting a number of solar cells and joining them into panels with specific frames and connectors.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

With traditional energy source prices on the rise, there is a need for a low cost way of producing electricity using a low cost solar cell device. Conventional solar cell manufacturing processes are highly labor intensive and have numerous interruptions that can affect throughput, solar cell cost, and device yield. As the demand for using increasingly larger substrates continues to grow, the method for testing and qualification of the solar cells has gained increased importance to ensure the fitness of the solar cells in normal use.

Therefore, there is a need for a device that simulates environmental conditions and a method for testing the solar cell performance under the simulated conditions.

### SUMMARY OF THE INVENTION

A method and apparatus for exposing a solar device to simulated environmental conditions is described. In one embodiment, a chamber is described. The chamber includes a frame defining a partial enclosure having an interior volume, the frame comprising a door selectively sealing an opening in the frame, a plurality of lighting devices coupled to the enclosure interior of an open wall, each of the plurality of lighting devices being positioned to direct light toward an upper surface of a platen disposed in the interior area, and a plurality of fan units positioned in an opening formed in a sidewall of the frame, each of the plurality of fan units positioned to direct ambient air flow from the outside of the enclosure toward the platen and between the plurality of lighting devices to exit through the open wall.

In another embodiment, an environmental simulator apparatus is described. The apparatus includes an enclosure defining a testing region, the enclosure having a plurality of open areas that are in communication with ambient atmosphere, a plurality of first fan units positioned to direct ambient air flow from outside of the enclosure and across the testing region, a probe nest positioned to make electrical connection with one or more terminals of a solar module positioned in the testing region, and a light source configured to emit optical energy simulating the solar spectrum in a direction that is substantially normal relative to an upper surface of the solar module.

In another embodiment, a method for exposing a solar device to simulated environmental conditions is described. The method includes providing a solar device to a chamber, the chamber having an environment that includes a light source simulating the solar spectrum and a first temperature configured to maintain a second temperature in the interior of the solar device that is less than the first temperature, and maintaining the first temperature during a test period.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is an isometric view of one embodiment of a testing chamber.

FIG. 1B is an isometric view of the testing chamber of FIG. 1A exposing the interior of the chamber.

FIG. 2A is a top plan view of the testing chamber of FIGS. 1A and 1B.

FIG. 2B is a side elevation view of the testing chamber of FIG. 2A.

FIG. 2C is a front elevation view of the testing chamber of FIGS. 2A and 2B.

FIG. 2D is a bottom view of the chamber of FIGS. 2A-2C.

FIG. 2E is a cross-sectional view of a platen taken along section A-A of FIG. 1B.

FIG. 3A is a simplified schematic diagram of one embodiment of a single junction amorphous or micro-crystalline silicon solar cell.

FIG. 3B is a simplified schematic diagram of one embodiment of a multi-junction solar cell.

FIG. 3C is a schematic plan view of one embodiment of a backside of a PV device.

FIG. 3D is a cross-sectional view of a single junction solar cell.

FIG. 3E is a schematic cross-sectional view of a PV device illustrating various scribed regions used to form the individual cells.

FIG. 4A is a schematic top view of a light soaking chamber showing one embodiment of a temperature control loop.

FIG. 4B is a schematic side view of a portion of the processing area of a light soaking chamber.

FIG. 4C is a schematic bottom view of a light soaking chamber showing one embodiment of a light soaking electrical test procedure.

FIG. 5 is a plan view of one embodiment of a solar module production line.

FIG. 6A is a schematic cross-sectional view of another embodiment of a light soaking chamber.

FIG. 6B is a plan view of one embodiment of a platen that is adapted for the light soaking chamber shown in FIG. 6A.

FIG. 7 is a schematic isometric view of another embodiment of a lighting array.

FIG. 8 is a flow chart showing one embodiment of a light soaking method.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The invention generally provides an apparatus and method for simulating the environmental conditions where a solar device is to be placed in service. The solar device as described herein includes a solar cell or solar modules having one or more solar cells and will be exemplarily referred to hereinafter as a photovoltaic (PV) device. The apparatus and method mimics a solar intensity and/or temperature conditions in a manner that simulates conditions the PV device may experience when put into service. In one embodiment, the apparatus exposes PV devices to a controlled illumination mimicking sunlight at a controlled temperature. In one aspect, the controlled illumination and/or the controlled temperature is utilized to produce defects in the PV device in order to determine the robustness of the PV device. Electrical characteristics of the PV device may be monitored and/or determined during the simulation or after the simulation. In one or more embodiments, apparatus and testing method may be utilized as part of a larger PV device production system, such as in a cluster tool or linear fabrication line, such as the SUNFAB™ solar module production line available from Applied Materials, Inc., of Santa Clara, Calif. In one aspect, the observations of electrical characteristics and/or robustness of the PV device under test will be monitored in-situ such that modifications to the production parameters of subsequent PV devices may be implemented in upstream processes

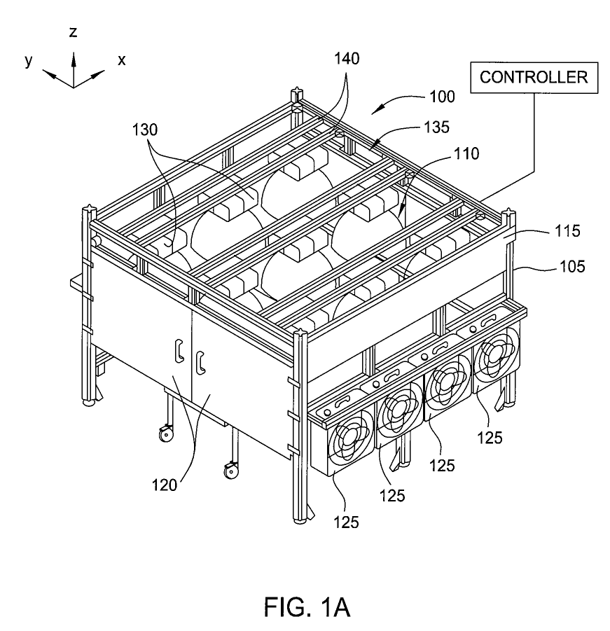

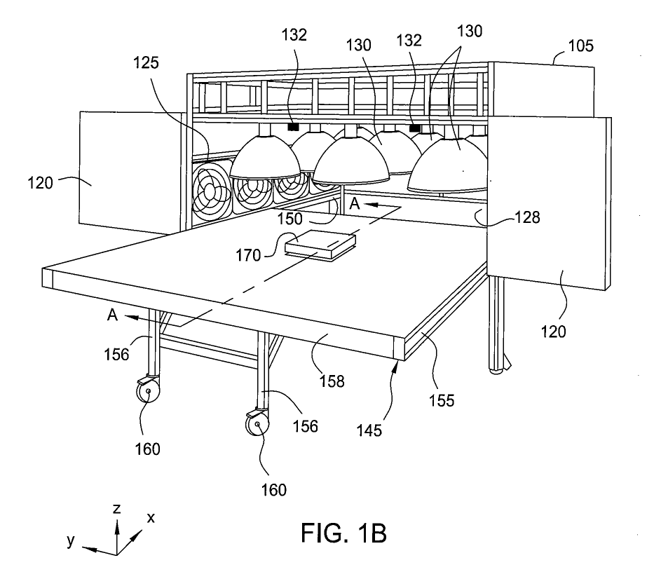

FIGS. 1A and 1B are isometric views of one embodiment of a light soaking chamber 100. The light soaking chamber 100 includes a frame 105 that defines an enclosure 110. The enclosure 110 includes sidewalls 115 that at least partially cover the frame 105 and one or more doors 120 that provide access to the interior of the enclosure 110. In the view of FIG. 1A the doors 120 are closed and in the view of FIG. 1B the doors 120 are open to expose a processing area 128 interior of the enclosure 110.

The chamber 100 also includes a plurality of air handling devices, such as one or more fan units 125 that are disposed about a perimeter of the frame 105. In this embodiment, four fan units 125 are disposed on a first side of the chamber 100 and four fan units 125 are disposed on an opposing second side of the chamber 100. A plurality of lighting devices 130 are disposed in the enclosure 110 adjacent an open wall 135 of the frame 105. Each of the plurality of lighting devices 130 are coupled to support members 140 coupled to the frame 105. Each of the lighting devices 130 are movably coupled to the support members 140 such that individual lighting devices 130 may be moved independently of each other in at least a lateral direction and/or a vertical direction. Each of the plurality of lighting devices 130 and the plurality of fan units 125 are coupled to a controller to control applied power to the respective devices of the chamber 100.

Referring to FIG. 1B, the chamber 100 includes a movable support surface or platen 145 that is adapted to support a PV device to be tested (not shown). In one embodiment, the platen 145 is cantilevered and/or rolled out of the enclosure 110 to load/unload a substrate and place the substrate in the processing area 128 in a position to be impinged by the lighting devices 130 and/or air from the fan units 125. In other embodiments (not shown), one or more PV devices may be transferred to the platen 145 and positioned in the processing area 128 by robotic equipment, such as an end effector or a conveyor system. In the embodiment shown in FIG. 1B, the platen 145 is coupled to the frame 105 by a linear slide mechanism 150 that movably supports the platen 145. The linear slide mechanism 150 may include bearings and/or a channel adapted to be coupled with a slot 155 formed in opposing sides of the platen 145. One or more rolling members 160 are shown coupled to the platen 145 to facilitate support of the platen 145 and moving of the platen 145 into and out of the enclosure 110. The one or more rolling members 160 are disposed on legs 156 that extend from a frame structure 158 on the underside of the platen 145. In one aspect, the frame structure 158 provides mechanical stability to the platen 145 in order to maintain planarity of the platen 145.

In one embodiment, the platen 145 is moved in and out of the enclosure 110 manually although an actuator or drive (not shown) may be coupled to the chamber 100 to move the platen 145. The one or more rolling members 160 may be wheels, casters, and the like.

The light soaking chamber 100 may also include one or more optical sensors 132 disposed in the enclosure 110. The optical sensors 132 may be an optical device directed toward the platen 145 and have a line-of-sight view of the upper surface of the platen 145 and/or a PV device (not shown) that may be disposed thereon. In one embodiment, at least one of the one or more optical sensors 132 are temperature sensing devices, light measurement devices, and combinations thereof. In one embodiment, at least one of the one or more optical sensors 132 are temperature sensing devices adapted to provide a metric of the temperature of the platen 145 and/or a temperature of a PV device or portion thereof. Examples of the optical sensors 132 include laser sensors, infrared sensors, a camera and combinations thereof.

The chamber 100 is configured to provide a controlled optical intensity that substantially mimics the terrestrial solar spectrum. In one embodiment, the plurality of lighting devices 130 deliver optical energy with the intensity of about 1 kilowatt/square meter (roughly equivalent to one (1) sun) that is directed toward the surface of the platen 145. In one aspect, the spatial uniformity of the optical energy from the lighting devices 130 is about 20%. For example, the spatial uniformity of the optical energy is between 0.8 suns to about 1.2 suns measured in a 1.5 square meter area of the surface of the platen 145. The plurality of lighting devices 130 are metal halide lamps, light emitting diodes (LED's), radio frequency plasma lamps, such as LIFI™ lighting devices available from the LUXIM® Corp. of Sunnyvale Calif., and combinations thereof. Each of the plurality of lighting devices 130 is independently controllable to dim or brighten on demand.

The chamber 100 is adapted to operate in ambient or atmospheric conditions in a clean room or other fabrication facility environment. Optical energy from the lighting devices 130 is configured to impinge the upper surface of the platen 145 and/or a PV device disposed on the platen 145 (not shown) and at least partially illuminate the processing area 128. In one embodiment, the platen 145 is made of a thermally conductive material such that absorbed optical energy from the lighting devices 130 may be distributed evenly across the surface of the platen 145. Examples of thermally conductive materials for the platen 145 include aluminum, copper and other thermally conductive materials. In one embodiment, the platen 145 includes a removable section 170 that exposes a channel or an opening formed through the platen 145 (both not shown). The opening or channel exposed by the removable section 170 is sized to receive a portion of a PV device (not shown). The frame 105 may be made of any lightweight structural materials. The fan units 125 are commercially available air handling units that are capable of speed adjustment. In one embodiment, the fan units 125 are adapted to direct air flow from the exterior of the chamber 100 toward a center of the processing area 128.

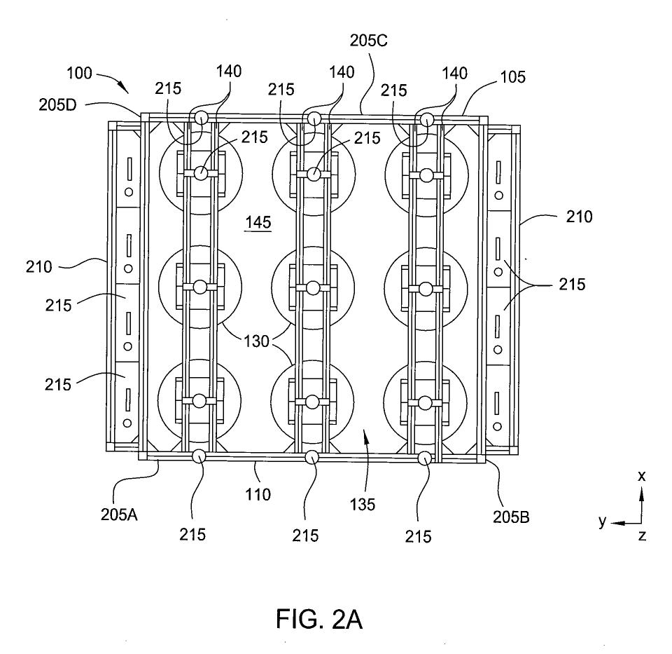

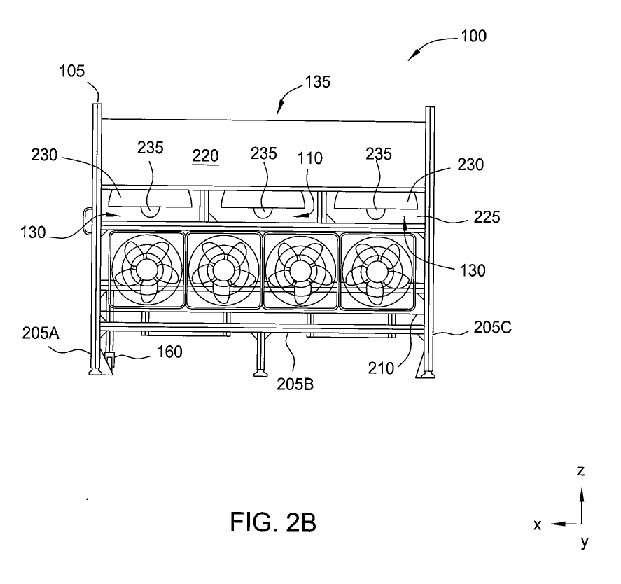

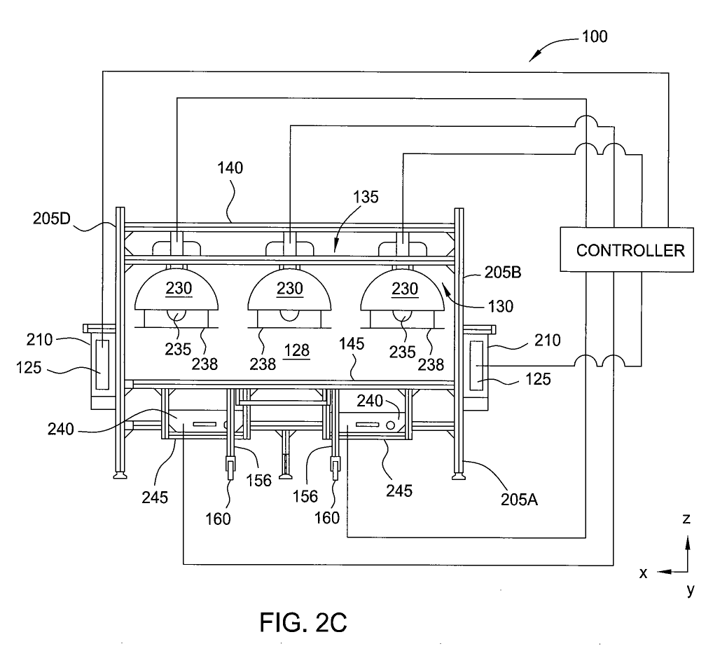

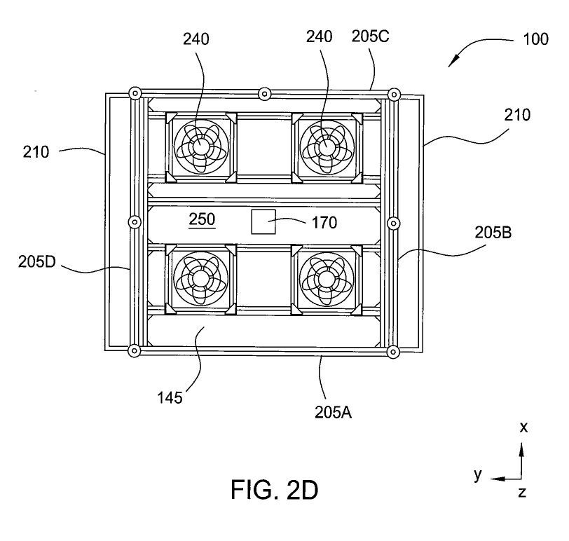

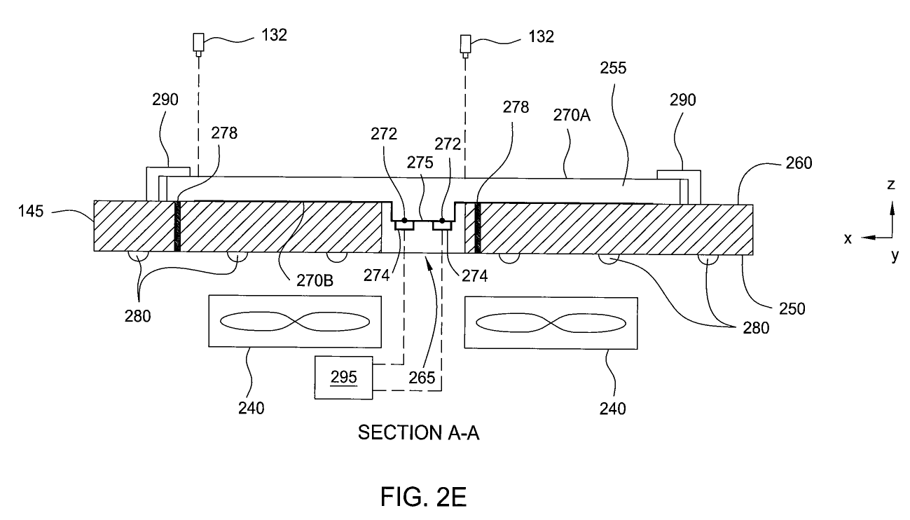

FIGS. 2A-2D are various views of the chamber 100 of FIGS. 1A and 1B. FIG. 2A is a top plan view of the chamber 100 showing a front side 205A, a back side 205C and adjacent sides 205B, 205B, wherein the front side 205A would include the doors 120. Each of the fan units 125 are coupled to the frame 105 by respective racks 210 that support the fan units 125 at a desired orientation relative to the enclosure 110. In one embodiment, the angular orientation of the fan units 125 may be adjusted at about 0 degrees to about 20 degrees off normal relative to the plane of the upper surface of the platen 145. In this manner, air flow from each of the plurality of fan units 125 may be directed downward and toward the upper surface of the platen 145. Each of the plurality of lighting devices 130 is coupled to the frame 105 in a manner that allows independent lateral (X and/or Y direction) and/or vertical (Z direction) movement of the lighting devices 130 relative to the frame 105. In one embodiment, each of the lighting devices 130 is coupled to a support member 140 by an adjustment device 215. Additionally or alternatively, each of the support members 140 are coupled to the frame 105 by an adjustment device 215. The adjustment device 215 is adapted to facilitate lateral and/or vertical adjustment of one or more of the lighting devices 130 and/or support members 140. The adjustment device 215 may be a manual adjustment device or an automated adjustment device. Examples of the adjustment device 215 include threaded devices, fasteners, knobs, set screws, lever or vise type mechanisms, actuators, and the like.

The number of lighting devices 130 is adapted for various sizes of PV devices and/or the optical intensity of each of the lighting devices 130. Factors such as heat generated and/or spatial uniformity provided by each of the lighting devices 130 may also be considered. In the embodiment shown, nine lighting devices 130 are included in the chamber 100 in a three×three pattern. The nine light configuration may be suitable for PV devices having dimensions of about 1.1×1.3 meters. Smaller PV devices, such as less than 1.1×1.3 meters may use only six of the lighting devices 130. Alternatively, nine of the lighting devices 130 may be provided on the chamber 100 and a portion of the lighting devices 130 may be dimmed or turned off when smaller PV devices are tested. Larger PV devices may require a greater number of the lighting devices 130. For example, when a PV device having dimensions of about 2.2×2.6 meters is tested, the chamber 100 may include twenty five lighting devices 130. In one embodiment, the twenty five lighting devices 130 may be included in the chamber 100 in a five×five pattern. Additionally, when PV devices having dimensions less than the 2.2×2.6 meters are tested, one or more of the twenty five lighting devices 130 may be dimmed or turned off during testing.

In one embodiment, air flow is directed from the exterior of the chamber 100 to regulate temperature within the enclosure 110. In this embodiment, the chamber 100 is at least partially open to ambient environment in order to exhaust air from the processing area 128. In one example, a majority of the air flow from the fan units 125 is forced from the exterior of the chamber 100 and is exhausted through the open wall 135 of the frame 105. The frame 105 also includes partial sidewalls 220 as shown in the side elevation view of the chamber 100 of FIG. 2B. For example, the sides 205B and 205D (205D not seen in this view) include open areas 225 that allow air to enter or exit the enclosure 110. In other embodiments, air from the exterior of the chamber 100 is directed through the open wall 135 and/or the open areas 225 and exhausted by the fan units 125. Some of the plurality of lighting devices 130 are visible through the open areas 225 of the frame 105. In one embodiment, the plurality of lighting devices 130 include a reflector 230, such as a parabolic reflector, that at least partially houses a lamp 235.

FIG. 2C is a front elevation view of the chamber 100 of FIGS. 2A and 2B with the doors removed to expose the processing area 128. In this view, additional air handling units referred to as fan units 240 are shown on a side of the platen 145 opposite the processing area 128. The fan units 240 are disposed in frames 245 that support the fan units 240 at a desired orientation relative to the platen 145. Each of the plurality of lighting devices 130 and the fan units 125, 240 are coupled to a controller so power to individual lighting devices 130 and the fan units 125, 240 may be controlled. Also shown in FIG. 2C are diffusive members 238 disposed between the lamps 235 and the platen 145. Each of the diffusive members 238 may be a transparent, or semi-transparent material that is adapted to evenly distribute or filter light from the lamps 235. In one embodiment, the diffusive members 238 are utilized to at least partially block or filter light from one or more of the plurality of lighting devices 130. In one aspect, the diffusive members 238 are used to tune the optical intensity in the processing area 128.

In one embodiment of a light soaking chamber 100, the evenly distributed or filtered light is at least partially shaded to simulate shading of the solar cells when in use in order to create a “hot spot” in the PV device. Generally, a hot spot in a PV device is created when minimal or reduced electrical current is produced by the shaded solar cells in the PV device while unshaded solar cells are generating electrical current. As the solar cells in the PV device are connected in series, the electrical current from the unshaded solar cells must pass through the shaded cells. Typically, a reverse bias is created in the shaded solar cells which results in heat being generated in the shaded solar cells. The resulting heat can damage the PV device or layers in each of the solar cells. Therefore, there is an ongoing challenge to mitigate the creation of hot spots and other defects in PV devices and the light soaking chamber 100 is utilized as an analysis tool to address these challenges.

FIG. 2D is a bottom view of the chamber 100 of FIGS. 2A-2C showing four fan units 240 positioned to direct air flow to a major side or a lower surface 250 of the platen 145. Also shown is the removable section 170 of the platen 145 that may be removed to expose an opening through the platen 145.

FIG. 2E is a cross-sectional view of the platen 145 taken along section A-A of FIG. 1B. A PV device 255 is also shown disposed on an upper surface 260 of the platen 145. The PV device 255 includes an upper side 270A configured to face a light source such as the sun or the lighting devices 130 (not shown) and a lower surface or backside 270B. The upper surface 260 of the platen 145 includes a planar surface to provide intimate contact between the upper surface 260 of the platen 145 and the backside 270B of the PV device.

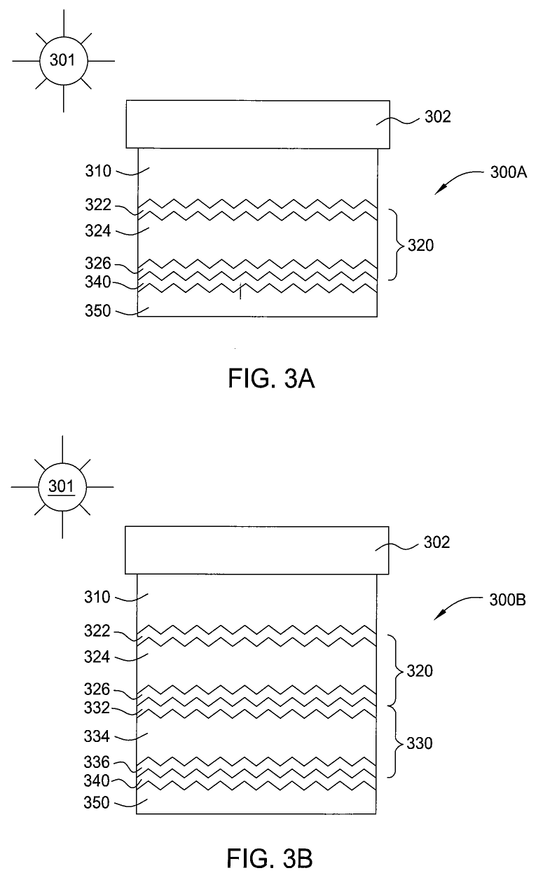

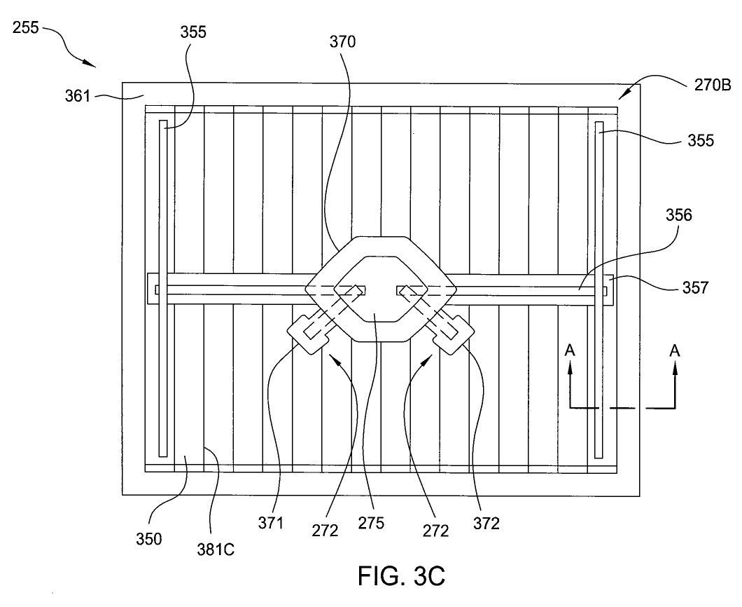

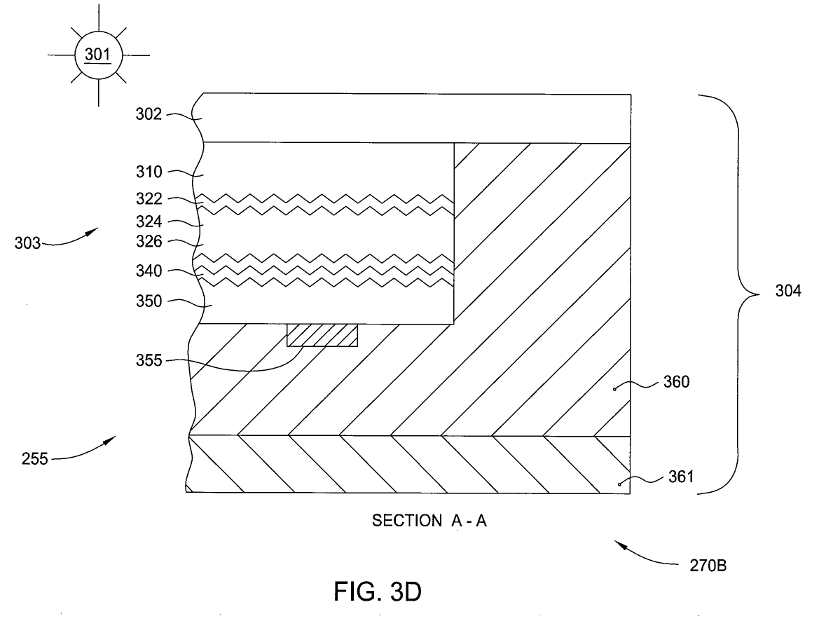

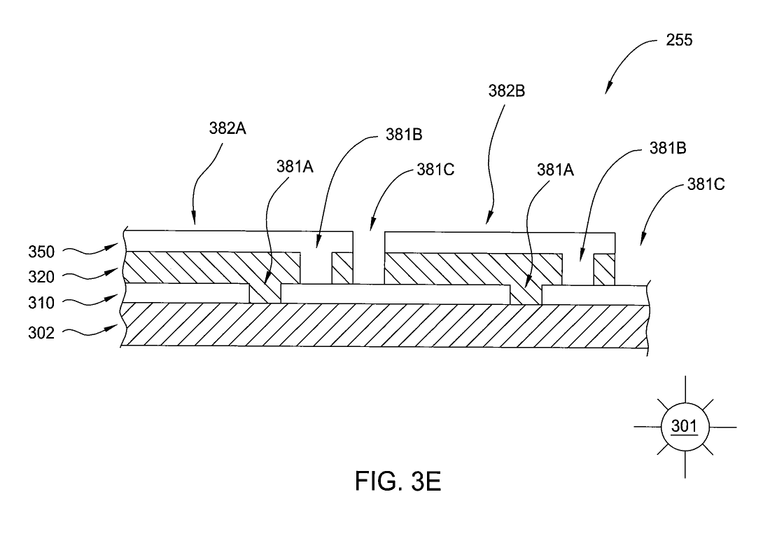

In this embodiment, the removable section 170 (FIG. 1B) of the platen 145 is removed to expose an opening 265 formed in the platen 145. In one embodiment, the opening 265 is configured to provide access to terminals 272 coupled to the PV device 255 disposed in a junction box 275 that is part of the PV device 255. In one aspect, the chamber 100 includes probes or electrical leads 274 that are attached to the terminals 272 of the PV device 255. In one embodiment, the junction box 275 protrudes from the backside 270B of the PV device 255 and the opening 265 is sized to receive the protruded portion of the backside 270B. Sizing the opening 265 to receive the junction box 275 in this manner allows the majority of the backside 270B of the PV device 255 to be in intimate contact with the upper surface 260 of the platen 145. The opening 265 also allows coupling of the electrical leads 274 to the terminals 272. The electrical leads 274 are coupled with a computer 295 adapted to store data from the PV device 255. Examples of a PV device 255 that may be tested by the light soaking chamber 100 of FIGS. 1A-2E are shown in FIGS. 3A-3E.

Temperature of the PV device 255 and the platen 145 are controlled during testing in the chamber 100. In one example of an environmental simulation and/or a testing process, the PV device 255 is heated and maintained at temperature between about 40° C. and about 60° C. with a maximum deviation of about 10 percent across the upper surface 260 of the platen 145. In another embodiment, the temperature of the platen 145 and/or the PV device 255 is controlled within about +/−3° C. in any 1.5 m² area. Temperature control of the platen 145 and/or the PV device 255 is provided by controlling the output of the lighting devices 130 and the fan units 125 and 240 using one or more sensors 278. Each of the one or more sensors may be thermocouple devices, pyrometers, spectrometers, and combinations thereof.

In one embodiment, the one or more sensors 278 are positioned to determine temperatures at the perimeter of the PV device 255 and at or near the center of the PV device 255. While the one or more sensors 278 are shown disposed in the body of the platen 145, the sensors 278 may be coupled to a surface of the PV device 255 outside of the platen 145. For example, the sensors 278 may be manually positioned and/or coupled a perimeter of the PV device 255 and to a center of the PV device 255 through the opening 265. In other embodiments, temperature sensing may be provided by a sensor 132 that is configured to view the PV device 255. In one embodiment, the sensor 132 is an infrared camera adapted to view the upper side 270A of the PV device 255. In this embodiment, the sensor 132 is configured to provide a temperature metric of components within the PV device 255.

In one embodiment, cooling of the platen 145 and/or the PV device 255 is provided by the fan units 125 and/or 240 to control and maintain a desired temperature of the solar cell during testing. In another embodiment, the platen 145 may include temperature control channels 280 disposed in or on the platen 145. The channels 280 may be coupled to a temperature control fluid source such as water, ethylene glycol, nitrogen or other temperature control fluid adapted to heat or cool the platen 145. In one embodiment, the channels 280 are adapted to flow a heated fluid, such as water. The fluid may be heated by one or more heating devices (not shown), such as a compressor, that controls the temperature of the fluid as it is introduced into the channels 280. In one aspect, the temperature of the fluid exiting the channels 280 may be monitored and power to the heating devices may be adjusted to adjust the temperature of the fluid entering the channels 280. In another embodiment, the platen 145 may include an embedded heating element (not shown). While some embodiments are described as supporting the PV device 255 on the platen 145 in a horizontal orientation (X or Y direction) where gravity may be utilized, the platen 145 may be modified to include support members 290 to allow the PV device 255 to couple with the platen 145. In one embodiment, the platen 145 may be vertically orientated (Z direction) or moved to a vertical orientation to allow testing of the PV device 255 in a vertical orientation.

FIG. 3A is a simplified schematic diagram of a single junction amorphous or micro-crystalline silicon solar cell 300A that can be formed in the PV device 255 of FIG. 2E and light soaked and/or analyzed in the chamber 100. The single junction amorphous or micro-crystalline silicon solar cell 300A is oriented toward a light source or solar radiation 301. During testing, the solar radiation 301 is provided by the lighting devices 130. The solar cell 300A generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300A further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to, a material selected from the group consisting of Al, Ag, Ti, Cr, Au, Cu, Pt, alloys thereof, and combinations thereof.

FIG. 3B is a schematic diagram of an embodiment of a solar cell 300B, which is a multi-junction solar cell that is oriented toward the light or solar radiation 301. The solar cell 300B comprises a substrate 302, such as a glass substrate, polymer substrate, metal substrate, or other suitable substrate, with thin films formed thereover. The solar cell 300B may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340.

In the embodiment shown in FIG. 3B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3C is a plan view that schematically illustrates an example of the backside 270B of a PV device 255. FIG. 3D is a side cross-sectional view of a portion of the PV device 255 illustrated in FIG. 3C (see section A-A). While FIG. 3D illustrates the cross-section of a single junction solar cell similar to the configuration described in FIG. 3A, this is not intended to be limiting as to the scope of the invention described herein.

As shown in FIGS. 3C and 3D, the PV device 255 may contain a substrate 302, the solar cell device elements (e.g., reference numerals 310-350), one or more internal electrical connections (e.g., side buss 355, cross-buss 356), a layer of bonding material 360, a back glass substrate 361, and a junction box 275. The junction box 275 generally includes at least one terminal 272 which are in electrical communication with the back contact layer 350 and active regions of the PV device 255. In some embodiments, the junction box 275 may generally contain two junction box terminals 371, 372 that are electrically connected to portions of the PV device 255 through the side buss 355 and the cross-buss 356, which are in electrical communication with the back contact layer 350 and active regions of the solar cell 300A or 300B. To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a bonding material 360 is referred to as a composite solar cell structure 304.

FIG. 3E is a schematic cross-sectional view of a PV device 255 illustrating various scribed regions used to form the individual cells 382A-382B within the PV device 255. As illustrated in FIG. 3E, the PV device 255 includes a transparent substrate 302, a first TCO layer 310, a first p-i-n junction 320, and a back contact layer 350. Three laser scribing steps may be performed to produce trenches 381A, 381B, and 381C, which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single junction type solar cell is illustrated in FIG. 3E this configuration is not intended to be limiting to the scope of the invention described herein.

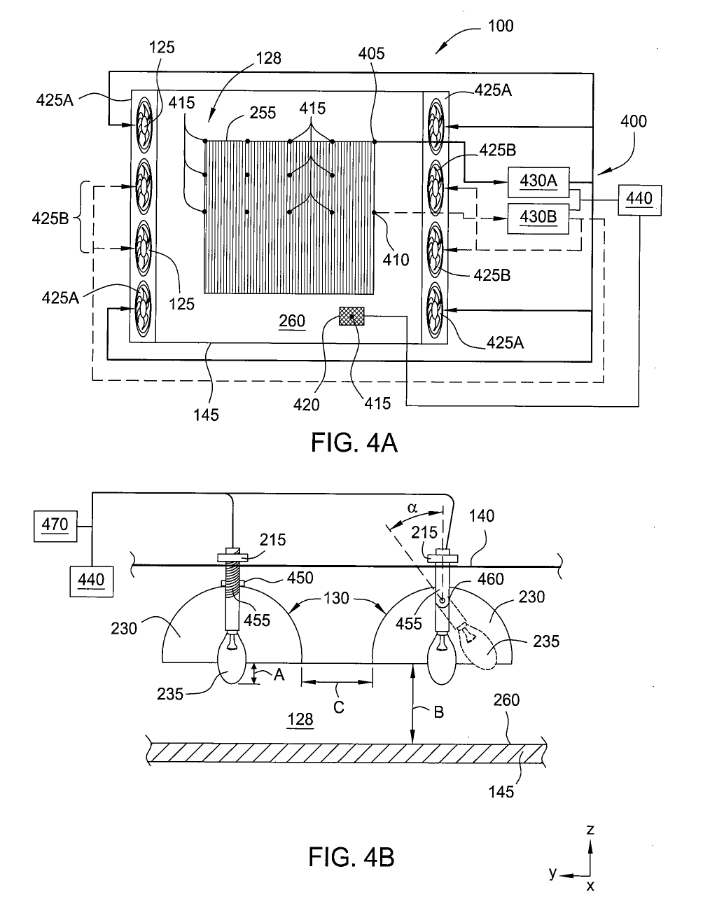

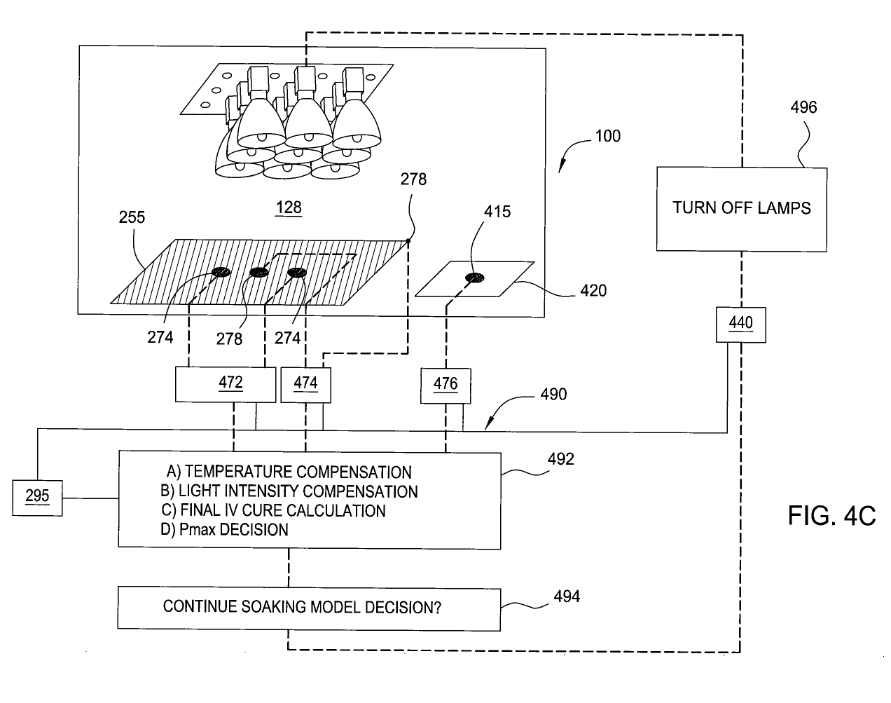

FIG. 4A is a schematic top view of a light soaking chamber 100 showing one embodiment of a temperature control loop 400 utilized in a light soaking process. The temperature control loop 400 may be utilized in one or a combination of the setup of the chamber 100, environmental simulation in the chamber 100 and/or testing of a PV device 255 in the chamber 100. During environmental simulation and/or testing, a PV device 255 is supported on the upper surface 260 of the platen 145 as shown. During the environmental simulation or testing process, the temperature of the PV device 255 must be elevated and/or maintained to temperatures that simulate the environment the PV device 255 may encounter when put into service. Thus, the environment in the chamber 100 must be configured to produce and maintain a predetermined temperature. In this Figure, a PV device 255 is shown on the upper surface 260 of the platen 145. However, during a setup procedure to realize a desired temperature, a dummy substrate may be used in lieu of an actual PV device to determine the initial temperature of the chamber 100. Therefore, the PV device 255 may be used in this Figure for reference purposes only to aid the reader in understanding the invention. Alternatively, an actual PV device 255 may be utilized to determine the initial temperature during a setup process. In another alternative, a reference cell 420, such as a photosensing device or photo-absorbing device may be used alone or in combination with the dummy substrate or an actual PV device in order to facilitate monitoring and control of the optical energy from the plurality of lighting devices 130.

Temperatures in the chamber 100 are closely monitored by at least one temperature indication point 405 at a perimeter of the PV device 255 and at least one temperature indication point 410 at a center of the PV device 255. Additionally, a plurality of temperature indication points 415 may be monitored during the setup, environmental simulation and testing of the PV device 255. In one embodiment, the temperature indication points 405, 410 and 415 represent reference points for temperature measurement using one or a combination of the sensors 132 (FIGS. 1B and 2E) and the sensors 278 (FIG. 2E). In another embodiment, the temperature indication points 405, 410 and 415 indicate positions of discrete temperature sensors, such as the sensors 278. In one embodiment, a pattern of temperature indication points including 405, 410 and 415 may be monitored during setup, environmental simulation and/or testing of the PV device 255. In one aspect, a grid pattern of temperature indication points may be monitored during setup, environmental simulation and/or testing of the PV device 255. For example, a portion of the PV device 255, such as the center and at least one edge of the PV device 255 may be monitored using about twenty five sensors. Alternatively or additionally, a reference cell 420 may be placed on the upper surface 260 of the platen 145. In one embodiment, the reference cell 420 is a separate PV device, a photosensor, or other photoconductive device. The reference cell 420 also includes a temperature indication point 415 that may be a reference point for a temperature sensor as described above.

In one embodiment, the plurality of fan units 125 are divided into a first set of fan units 425A and a second set of fan units 425B adapted to provide air flow across an edge and a center, respectively, of the PV device 255. Each of the temperature indication points 405 and 410 are in communication with one or more controllers 430A and 430B. In one embodiment, the controllers 430A and 430B are speed controllers adapted to control the air flow of each of the plurality of fan units 125 individually. In another embodiment, the controllers 430A and 430B are adapted to control the first set of fan units 430A and second set of fan units 430B, respectively. In one aspect, the controllers 430A and 430B are controlled loop feedback controllers, such as a proportional-integral-derivative (PID) controller. In another embodiment, each of the controllers 430A and 430B are coupled to a master PID controller 440.

FIG. 4B is a schematic side view of a portion of the processing area 128 of a light soaking chamber 100. In this Figure, two of the plurality of lighting devices 130 are shown with the reflector 230 in cross-section. While the plurality of lighting devices 130 provide heat to the processing area 128, temperature control in the processing area 128 is also provided by adjustment of the lighting devices 130. For example, the height of the reflectors 230 and/or lamps 235 may be adjusted relative to the upper surface 260 of the platen 145. In one embodiment, the height of the reflector 230 is adjusted relative to the lamp 235 (distance A) by rotating the reflector 230. In one aspect, the reflector 230 may be coupled to an adjustment device 450, such as a nut, that is rotated relative to a shaft 455 having threads. Alternatively or additionally, the reflector 230 and lamp 235 may be adjusted relative to the upper surface 260 of the platen 145 (distance B) by the adjustment device 215, which may be a nut adapted to rotate relative to the shaft 455. Additionally, the distance between lamps 235 and/or the reflectors 230 (distance C) may be adjusted using the adjustment devices 215. In an additional or alternative embodiment, the lamps 235 may be configured to adjust angularly relative to the upper surface 260 of the platen 145. In one aspect, the shaft 455 includes a swivel device 460 adapted to rotate the lamp 235 and lock the lamp 235 at an angle α relative to a longitudinal axis of the shaft 455. Thus, optical and/or thermal intensity of the lighting devices 130 may be controlled using one or a combination of linear adjustments (distances A, B and C) and angular adjustments (angle α).

Each of the lighting devices 130 are in communication with the master PID controller 440 that provides on/off and power control to the individual lighting devices 130. A separate controller 470 may be coupled with an actuator (not shown) that is utilized to adjust distances A, B and C and/or the angle α based on instructions from the master PID controller 440. Alternatively, the adjustments of distances A, B and C and/or the angle α may be performed manually based on feedback from the master PID controller 440.

FIG. 4C is a schematic bottom view of the chamber 100 showing one aspect of a light soaking electrical test procedure 490. In this Figure, the platen is not shown to more clearly describe the interface between the chamber 100 and the PV device 255. The temperature of the PV device 255 is monitored by at least one sensor 278 in communication with a perimeter of the PV device 255 and another sensor 278 in communication with a center of the PV device 255. The electrical leads 274 are coupled to the PV device 255 to monitor signals from the PV device 255. Temperature data from the sensors 278 and electrical data from the PV device 255 is collected in a computer 295. In one embodiment, a reference cell 420 (e.g., thermopile) is utilized to monitor conditions in the processing area 128. In this embodiment, temperature data and/or light intensity data is collected in the computer 295.

In one example, the computer 295 includes an electrical output recording program 472 that analyzes and records a raw current/voltage (IV) data from the PV device 255. The computer 295 also includes a temperature recording program 474 that monitors and/or collects temperature data from the PV device 255. In embodiments where a reference cell 420 is utilized, the computer 295 also includes a reference cell recording program 476 for the reference cell 420. Data, such as temperature and/or optical intensity experienced by the reference cell 420 is monitored and/or recorded by the reference cell recording program 476. Thus, the computer 295 enables monitoring and/or recording of temperatures and electrical characteristics of the PV device 255 for future use by the user or computer 295. In embodiments where the reference cell 420 is used, the computer 295 monitors and/or records data from the reference cell 420 that is indicative of the conditions of the processing area 128 and/or the environment surrounding the PV device 255.

In one embodiment, the testing procedure 490 includes utilizing the data recorded by the computer 295 to adjust conditions in the processing area 128 and/or determine the electrical characteristics of the PV device 255. In some embodiments, data from the PV device 255 is utilized to adjust process recipes in upstream processes to fabricate a more robust PV device. In one embodiment, the computer 295 enables real time monitoring of the PV device 255 and/or adjustment of conditions in the processing area 128 as shown at 492. For example, temperature compensation (A) of the PV device 255 may be monitored and controlled. In one aspect, the temperature may be monitored to enable a comparison with IV curve. In another example, light intensity compensation (B) may be monitored and controlled. In one aspect, data from the reference cell 420 is compared with electrical output of the PV device 255. In another example, electrical characteristics of the PV device may be monitored utilizing the data from the computer 295. In one aspect, a final IV curve calculation (C) may be determined. In another aspect, a maximum power (Pₘₐₓ) determination (D) of the PV device 255 may be obtained by the computer 295. In this embodiment, the PV device 255 may be classified or rated based on electrical output.

In one embodiment, the testing procedure 490 includes a determination 494 that includes a decision for continuing the light soaking process. In one aspect, the determination 494 may be based on conditions in the processing area 128 and/or the temperature and/or optical intensity experienced by the PV device 255. For example, if the temperature of the PV device 255 is not stabilized, the determination may be positive to continue the light soaking process in an attempt to stabilize the PV device 255. The computer 295 is in communication with the master PID controller 440 and temperature and/or optical intensity in the processing area 128 may be modified. If the determination is negative, which may indicate stabilization of the PV device 255, the PID controller 440 may turn off the lighting devices 130 as shown at 496. The determination 494 may also include continuing the light soaking process to test the PV device 255 under different environmental conditions. For example, electrical characteristics of the PV device 255 may be tested (i.e., monitored, recorded and/or rated) at a first temperature and tested again at a second temperature that is less than or greater than the first temperature.

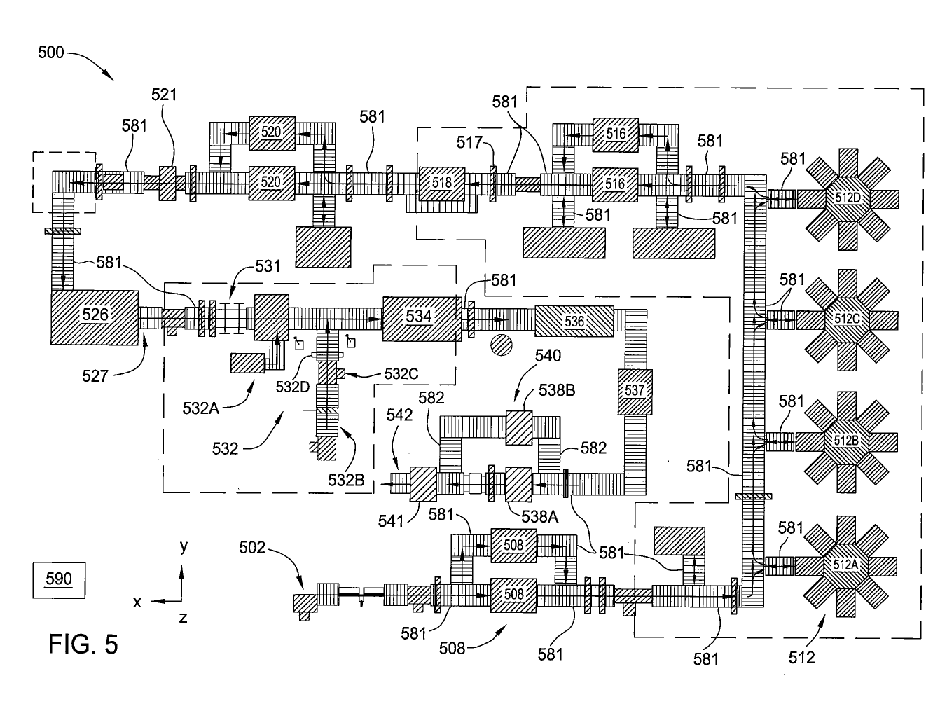

FIG. 5 is a plan view of one embodiment of a solar module production line 500 having the light soaking chamber as one component. In one illustrative processing sequence a substrate 302 is loaded into a loading module 502 found in the solar module production line 500. The substrates 302 are transferred to various components of the solar module production line 500 along conveyors 581 and/or by other devices or means, such as manually or with robotic equipment. In one embodiment, the substrates 302 are received in a “raw” state where the edges, overall size, and/or cleanliness of the substrates 302 are not well controlled. However, typically, it is advantageous to receive “raw” substrates 302 that have a first TCO layer 310 already deposited on a surface of the substrate 302.

Next, the substrate 302 is transported to a scribe module 508 in which a front contact isolation process is performed on the substrate 302 to electrically isolate different regions of the substrate 302 surface from each other. Next, the substrate 302 is transported to a processing module 512 in where one or more photoabsorber deposition processes is performed on the substrate 302. The one or more photoabsorber deposition processes may include one or more preparation, etching, and/or material deposition steps that are used to form the various regions of the solar cell device. The one or more deposition processes may include a series of sub-processing steps that are used to form layers of the solar cell 300A and 300B. In general, the one or more photoabsorber deposition processes are performed in one or more cluster tools (e.g., cluster tools 512A-512D) found in the processing module 512 to form one or more layers in the solar cell device formed on the substrate 302.

Next, the substrate 302 is transported to a scribe module 516 in which an interconnect formation process is performed on the substrate 302 to electrically isolate various regions of the substrate 302 surface from each other. Material is removed from the substrate 302 surface by use of a material removal step, such as a laser ablation process. In another embodiment, a water jet cutting tool or diamond scribe is used to isolate the various regions on the surface of the substrate 302.

Next, the substrate 302 may be transported to an inspection module 517 in which an inspection process may be performed and metrology data may be collected and sent to the system controller 590. In one embodiment, the substrate 302 passes through the inspection module 517 and the substrate 302 is optically inspected. Images of the substrate 302 are captured and sent to the system controller 590, where the images are analyzed and metrology data is collected and stored in memory. In one embodiment, the metrology data is used to modify one or more upstream processes.

Next, the substrate 302 is transported to a processing module 518 in which a back contact formation process is performed on the substrate 302. The back contact formation steps may include one or more preparation, etching, and/or material deposition steps that are used to form the back contact regions of the solar cell device. In one embodiment, one or more PVD steps that are used to form the back contact layer 350 on the surface of the substrate 302. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the substrate 302.

Next, the substrate 302 is transported to a scribe module 520 in which a back contact isolation process is performed on the substrate 302. In one embodiment, a 5.7 m² substrate laser scribe module, available from Applied Materials, Inc., is used to accurately scribe the desired regions of the substrate 302. In one embodiment, the laser scribe process uses a 532 nm wavelength pulsed laser to pattern the material disposed on the device substrate 303 to isolate regions of the solar cell 300A, 300B. In another embodiment, a water jet cutting tool or diamond scribe is used to isolate the various regions on the surface of the substrate 302.

Next, the substrate 302 may be transported to an inspection module 521 in which an inspection process is performed and metrology data may be collected and sent to a system controller 590. In one embodiment, the substrate 302 passes through the inspection module 521 where the substrate 302 is optically inspected. Images of the substrate 302 are captured and sent to the system controller 590 where the images are analyzed and metrology data is collected and stored in memory. In one embodiment, the metrology data is used to modify one or more upstream processes, such as the front contact isolation process, the interconnect formation process, and/or the back contact isolation process.

The substrate 302 is next transported to a seamer/edge deletion module 526 in which a substrate surface and edge preparation process is performed to prepare various surfaces of the substrate 302. In one aspect, the surface and edge preparation process is utilized to prevent yield issues later on in the device formation process. In one embodiment, the substrate 302 is inserted into seamer/edge deletion module 526 to prepare the edges of the substrate 302. In another embodiment, the seamer/edge deletion module 526 is used to remove deposited material from the edge of the substrate 302 (e.g., about 10 mm) to provide a region that can be used to form a reliable seal between the substrate 302 and the back glass substrate 361 (FIG. 3D). Material removal from the edge of the substrate 302 may also be useful to prevent electrical shorts in the final formed PV device.

Next the substrate 302 is transported to a pre-screen module 527 in which optional pre-screen processes are performed on the substrate 302 to assure that the devices formed on the substrate surface meet a desired quality standard. In one embodiment, a light emitting source and probing device are used to measure the output of the formed solar cell device by use of one or more substrate contacting probes. If the module 527 detects a defect in the formed device it can take corrective actions or the solar cell can be scrapped.

Next the substrate 302 is transported to a bonding wire attach module 531 in which a bonding wire attach process is performed on the substrate 302. The bonding wire attach module 531 is used to attach the various wires/leads required to connect the various external electrical components to the formed solar cell device. Typically, the bonding wire attach module 531 is an automated wire bonding tool that is advantageously used to reliably and quickly form the numerous interconnects that are often required to form the large solar cells formed in the production line 500. In one embodiment, the bonding wire attach module 531 is used to form the side-buss 355 and cross-buss 356 (both shown in FIG. 3C) on the formed back contact layer 350. In this configuration the side-buss 355 may be a conductive material that can be affixed, bonded, and/or fused to the back contact layer 350 found in the back contact region to form a good electrical contact. In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 356, which is electrically connected to the side-buss 355 at the junctions, can be electrically isolated from the back contact layer(s) of the solar cell by use of an insulating material, such as an insulating tape. The ends of each of the cross-busses 356 generally have one or more leads that are used to connect the side-buss 355 and the cross-buss 356 to the electrical connections found in a junction box 275 (FIG. 3C), which is used to connect the formed solar cell to the other external electrical leads.

In the process, a bonding material and a back glass substrate 361 are prepared for delivery into the solar cell formation process. The preparation process is generally performed in a glass lay-up module 532, which generally includes a material preparation module 532A, a glass loading module 532B, a glass cleaning module 532C, and a glass inspection module 532D. The back glass substrate 361 is bonded onto the substrate 302 by use of a laminating process. In general, the bonding process requires the preparation of a polymeric bonding material that is to be placed between the back glass substrate 361 and the deposited layers on the substrate 302 to form a hermetic seal to prevent the environment from attacking the solar cell during its lifetime. A bonding material is prepared in the material preparation module 532A. The bonding material is then placed over the substrate 302 and the back glass substrate 361 is loaded into the loading module 532B. The back glass substrate is washed by the cleaning module 232C. The back glass substrate 361 is then inspected by the inspection module 532D, and the back glass substrate 361 is placed over the bonding material and the substrate 302.

Next the substrate 302, the back glass substrate 361, and the bonding material are transported to a bonding module 534 in which a lamination process is performed to bond the back glass substrate 361 to the substrate 302. In this process, a bonding material, such as polyvinyl butyral (PVB) or ethylene vinyl acetate (EVA), is sandwiched between the back glass substrate 361 and the substrate 302. Heat and pressure are applied to the structure to form a bonded and sealed device using various heating elements and other devices found in the bonding module 534. The substrate 302, the back glass substrate 361 and bonding material thus form a composite solar cell structure 304 that at least partially encapsulates the active regions of the solar cell device. In one embodiment, at least one hole formed in the back glass substrate 361 remains at least partially uncovered by the bonding material to allow portions of the cross-buss 356 or the side buss 355 to remain exposed so that electrical connections can be made to these regions of the solar cell structure 304 in subsequent processes.

Next the composite solar cell structure 304 is transported to an autoclave module 536 in which an autoclave process is performed on the composite solar cell structure 304. The autoclave process is utilized to remove trapped gasses in the bonded structure and assure that a good bond between the back glass substrate 361 and the substrate 302 is formed. In this process, a bonded solar cell structure 304 is inserted in the processing region of the autoclave module 536 where heat and high pressure gases are delivered to reduce the amount of trapped gas and improve the properties of the bond between the substrate 302, back glass substrate 361, and the bonding material. The processes performed in the autoclave module 536 are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the substrate 302, back glass substrate 361, and bonding material to a temperature that causes stress relaxation in one or more of the components in the formed composite solar cell structure 304.

Next the composite solar cell structure 304 is transported to a junction box attachment module 538 in which a junction box attachment process is performed on the solar cell structure 304. The junction box attachment module 538 is used to install a junction box 275 (FIG. 3C) on a partially formed PV device. The installed junction box 275 acts as an interface between the external electrical components that will connect to the formed PV device, such as other PV devices or a power grid, and the internal electrical connections points in the PV device. In one embodiment, the junction box 275 contains one or more terminals, such as terminals 371 and 372, so that the formed PV device can be easily and systematically connected to other external devices to deliver the generated electrical power. Thus, after the junction box 275 is attached to the composite solar cell structure 304, a sealed, operational PV device 255 is formed.

Next, the PV device 255 is transported to a testing module 540 where the PV device 255 is screened and analyzed to assure that the devices formed on the PV device 255 meet desired quality standards. In one embodiment, the testing module 540 includes at least one of a first testing chamber 538A and a second testing chamber 538B. In this embodiment, the first testing chamber 538A is located within the production line 500 such that PV devices 255 may be transported by the conveyor 581 through the testing chamber 538A while the second testing chamber 532B is located on a bypass conveyor 582 within the production line 500. In this embodiment, either of the first testing chamber 538A and the second testing chamber 538B are adapted to subject the PV device 255 to one or a combination of light and heat. In one embodiment, the production line 500 contains a plurality of testing chambers (e.g., reference numeral 538A, 538B) that are positioned in a parallel relationship to each other so that the solar cell throughput through the production line 500 can be achieved given the desired testing time in the testing chambers. In one configuration, the testing chambers 538A, 538B are each coupled to a plurality of conveyors 581 that are configured to transfer substrates to and from each of the testing chambers 538A, 538B.

In one embodiment, the first testing chamber 538A is a solar simulation chamber configured to subject the PV device 255 to optical energy and monitor electrical output of the PV device 255 when the PV device 255 is subjected to the optical energy. In one embodiment, the solar simulation chamber is adapted to emit a flash of light directed to the upper surface of the PV device 255 and power output of the PV device 255 is monitored and characterized. In another embodiment, the second testing chamber 538B is configured similarly to the light soaking chamber 100 as described herein. In some embodiments, the first testing chamber 538A may be configured as the light soaking chamber 100 and the second testing chamber 538B may be configured as a solar simulation chamber. In yet another embodiment, both of the first testing chamber 538A and the second testing chamber 538B may be configured as the light soaking chamber 100 as described herein such that the production line 500 includes two chambers adapted to perform a light soaking process and/or test the electrical performance of the PV device 255. In any of these embodiments, a light emitting source and probing device are used to measure the output of the PV device by use of one or more automated components that are adapted to make electrical contact with the terminals 371 and 372 in the junction box 275. If the testing module 540 detects a defect in the PV device 255, corrective actions may be performed or the PV device 255 may be scrapped.

Next the PV device 255 is transported to a support structure module 541 in which support structure mounting hardware is attached to the PV device 255. After completion of the mounting hardware attachment, the PV device 255 can easily be mounted and rapidly installed at a customer's site. The completed PV device 255 is then transported to an unload module 542 where the PV device 255 is removed from the solar module production line 500.

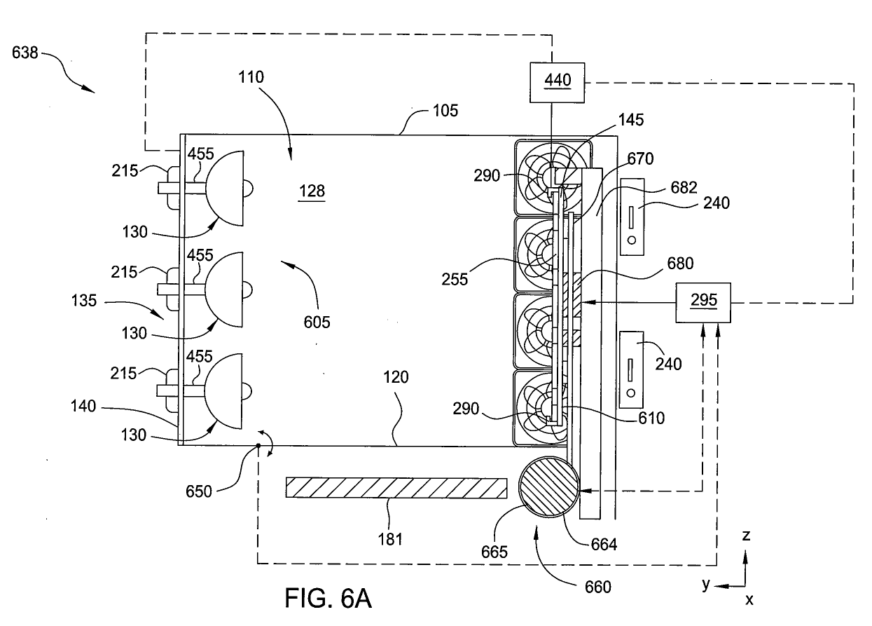

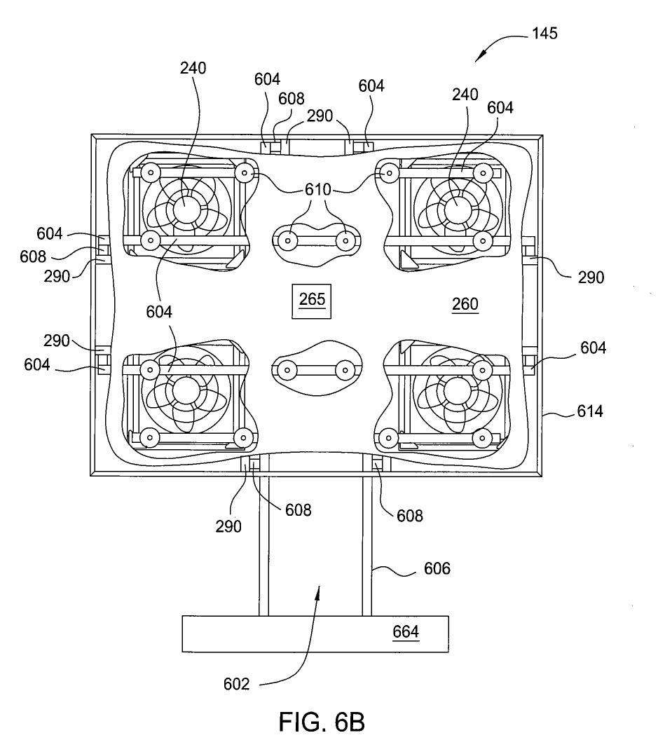

FIG. 6A is a schematic cross-sectional view of one embodiment of a light soaking chamber 638 that may be either of the first testing chamber 538A or second testing chamber 538B of FIG. 5. In this embodiment, the chamber 638 is adapted to direct optical energy from a light array 605 at a PV device 255 in a vertical orientation (Z direction).

The light soaking chamber 638 includes a positioning robot 660 and a platen 145 coupled to the positioning robot 660. The positioning robot 660 includes a rotary actuator 664 and a rotary brake 665. The platen 145 comprises a gantry structure 670 and a plurality of support elements 290 and 610 positioned to retain the PV device 255 against the gantry structure 670. In one embodiment, the support elements 290, 610 are vacuum gripping elements, mechanical gripping devices, and combinations thereof. The light soaking chamber 638 also includes an enclosure 110, which defines a processing area 128 where the PV device 255 is disposed for processing. The light array 605 is disposed in the processing area 128 for directing optical and thermal energy toward the PV device 255. The enclosure 110 includes a frame 105 and a door 120. The door 120 may be pivoted or retracted to allow the platen 145 to access the conveyor 581. In one embodiment, the door 120 includes a pivot mechanism 650 which may be a hinge or a rotary actuator. When the door 120 is opened, the rotary actuator 664 rotates the platen 145 into position to contact a PV device 255 on the conveyor 581. The rotary actuator 664 then rotates the platen 145 to a horizontal orientation where the platen 145 may receive a PV device 255. The support elements 290 and/or 610 are actuated and the rotary actuator 664 moves the platen 145 into the processing area 128 in a substantially vertical test position. The door 120 closes to exclude any extraneous light from the processing area 128 and is in a position that will not interfere with transfer of other PV devices on the conveyor 581. In this manner, a PV device 255 to be processed may be removed from the production line and processed in the light soaking chamber 638 without interfering with processing of other PV devices in the production line.

In one embodiment, the rotary actuator 664 includes a motor for rotating the platen 145 from a substantially horizontal (X or Y direction) loading or unloading position to a substantially vertical (Z direction) processing position. The rotary brake 665 provides holding capability in the event power is lost during movement of the platen 145. In the loading or unloading position, the platen 145 interacts with a conveyor 581 that moves the PV devices 255 into and out of the light soaking chamber 638. In one example, the platen 145 lifts an unprocessed PV device 255 off the conveyor 581, and replaces a processed PV device 255 back onto the conveyor 581.

The light soaking chamber 638 also includes a support member 682 for positioning a probe device or probe nest 680 when the PV device 255 is in the vertical position. The probe nest 680 generally includes electrical leads 274 (FIG. 2E) that couple to the junction box 275 on the PV device 255. The probe nest 680 provides data from the PV device 255 to a computer 295.

FIG. 6B is a plan view of one embodiment of a platen 145 that is adapted for the light soaking chamber 638 shown in FIG. 6A. The platen 145 includes a frame 602 having structural support elements 604 attached thereto for facilitating structural support of the platen 145. The platen 145 includes an upper surface 260 and an opening 265 formed therethrough. A portion of the platen 145 has been removed to show a plurality of fan units 245 disposed opposite the upper surface 260 of the platen 145.

In this embodiment, the platen 145 includes a plurality of support elements 610 and/or 290 adapted to facilitate support of a PV device (not shown). In one embodiment, actuators 608 are coupled to the support elements 290 to enable movement of the support elements 290. Each actuator 608 may be a linear actuator or servo motor that is powered electrically, pneumatically or hydraulically. In one embodiment, the support elements 610 are vacuum actuated pads or cups that are disposed in the upper surface 260 of the platen 145. Upon actuation, each of the support elements 610 grip a PV device and maintain contact between the PV device and the upper surface 260 of the platen 145.

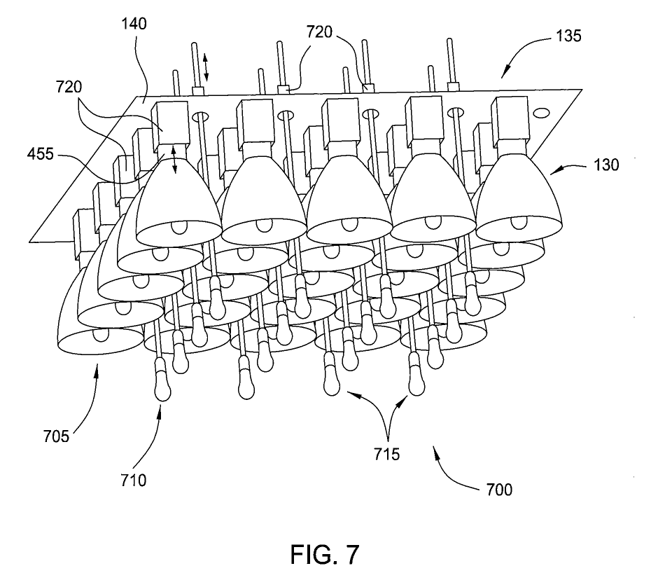

FIG. 7 is a schematic isometric view of another embodiment of a lighting array 700 that may be utilized in the light soaking chamber 100 or 638 as described herein. In this embodiment, the lighting array 700 is a mixture of two types of lamps consuming different levels of power arranged into a hybrid lamp array. The lighting array 700 includes a first light source array 705 and a second light source array 710. The first light source array 705 includes a plurality of first lamps arranged in a number of rows and columns and the second light source array 710 includes a plurality of second lamps arranged in a number of rows and columns. The number of rows and columns for each of the first light source array 705 and the second light source array 710 may be adjusted according to the size of the PV device to be tested.

In one embodiment, the first light source array 705 may include a plurality of first lighting devices 130 having a first power level while the second light source array 710 includes a plurality of second lighting devices 715 having a second power level. In one aspect, each of the plurality of first lighting devices 130 include metal halide lamps, LIFI™ lighting devices, and combinations thereof while each of the plurality of second lighting devices 715 include incandescent or tungsten lamps. In one embodiment, to achieve uniformed light distribution, the first light source array 705 is arranged in a first plane and the second light source array 710 is arranged in a second plane that is substantially parallel to the first plane. The distance between the first and the second planes may be adjusted accordingly to match desired spectrums. In one embodiment, the distance between the first and second planes may be adjusted manually or in an automated fashion by use of one or more actuators 720, such as a stepper motor or the like. In one embodiment, a desired spectrum may include a spectrum for sunlight that is substantially equivalent to one (1) sun. While not shown, each of the first light source array 705 and the second light source array 710 is in communication with a master PID controller.

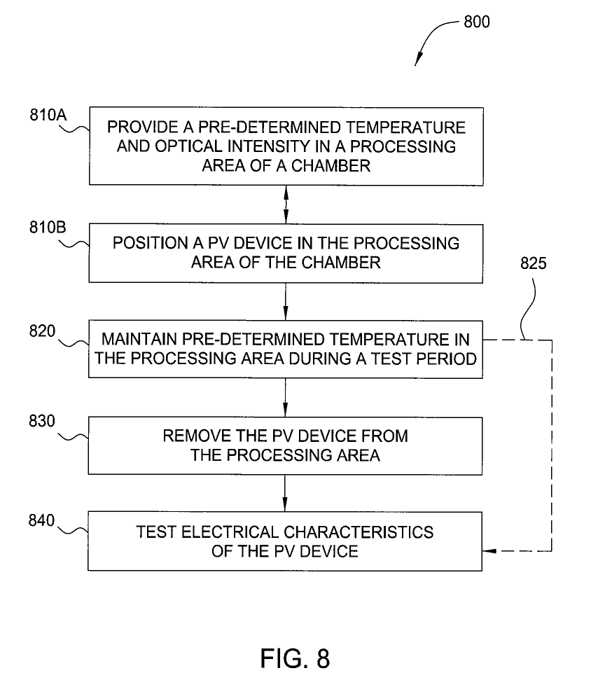

FIG. 8 is a flow chart showing one embodiment of a light soaking method 800. In this embodiment, the method 800 may be performed in the light soaking chamber 100 as a stand alone processing chamber or in the light soaking chamber 638 as part of a solar module production line. In one embodiment, the method 800 may be utilized to simulate environmental conditions in an effort to test and characterize a PV device 255. For example, the conditions in the processing area 128 may be set to provide thermal and optical energy in manner that creates light induced degradation (LID) of the PV device 255. Generally, LID is an effect of heat and light on components of the PV device 255 that may cause atoms and/or bonds between atoms found in one or more layers of a solar cell structure 304 in the PV device to change their position within one of the layers or change their physical or chemical structure, which reduces the efficiency of the solar cell structure 304. In one example, prolonged exposure of the PV device 255 to sunlight and/or heat serves to anneal solar cell structures within the PV device 255. In one aspect, the hydrogen bonds within the solar cell structure 304 may break down and trap carriers, which decreases the efficiency of the PV device 255. In one embodiment, inducing LID effects in the PV device 255 provides a metric that is indicative of quality of the PV device. For example, a PV device that has been light soaked by the methods described herein may be qualified using a percentage indicative of breakdown of the PV device 255. The metric may be utilized by the manufacturer or an end user to indicate quality of other PV devices 255 manufactured according to a process recipe. The metric may also be used as an indication of expected efficiency and/or lifetime of the PV devices 255 manufactured according to a specific process recipe.

In another aspect, a controlled optical intensity directed at the PV device 255 may be utilized to induce the formation of hot spots in the PV device 255. Shading of portions of the PV device 255 may be provided by one or more diffusive members 238 (FIG. 2C) disposed between the lamps 235 and the PV device 255. In other embodiment, shading of the PV device may be produced by covering a portion of the PV device with a material and/or turning off one or more of the lamps 235. In any of these embodiment, the conditions in the processing area 128 are adapted to simulate environmental conditions and/or extremes that the PV device 255 may encounter in service in an effort to maximize the usable lifetime and productivity of the PV device 255.

In the method 800, steps 810A and 810B are interchangeable depending on whether the conditions in the processing area 128 are desired to be provided prior to introduction of a PV device 255 or provided with a PV device 255 in the processing area 128. In one embodiment, the conditions in the processing area 128 are provided prior to transfer of a PV device 255 into the processing area 128 as shown at 810A. Temperature and optical intensity in the processing area 128 may be set during a ramp-up period and monitored and/or tuned to reach a steady state prior to introduction of a PV device 255 to be tested. Temperature may be monitored using discrete temperature sensors, such as thermocouples or pyrometers, disposed in or on the platen 145. A photo-sensor, a spectrometer or a reference cell may be used to monitor and facilitate tuning of optical intensity. In one embodiment, temperature is monitored using the optical sensors 132 (FIG. 2E). After the temperature in the processing area 128 has reached a desired set-point, a to-be-tested PV device 255 may be provided in the processing area 128.

In one aspect, the desired optical intensity includes providing optical energy with the intensity of about 1 kilowatt/square meter (roughly equivalent to one (1) sun) that is substantially directed toward the upper surface 260 of the platen 145. Additionally, the desired temperature set-point is between about 40° C. and about 60° C. measured at a p-i-n junction 320 and/or 330 (FIGS. 3A and 3B). In a specific embodiment, the temperature of the to-be-tested PV device 255 is desired to be about 50° C. measured at a p-i-n junction 320 and/or 330 near a center and perimeter of the PV device 255. The master PID controller 440 may be used to maintain the set-point temperature of the PV device 255 within about +/−3° C. in any 1.5 m² area.

In one embodiment, the desired junction temperature may be determined by discrete temperature sensors in or on the platen 145 and/or the optical sensors 132. In one aspect, the temperature of the upper surface 260 of the platen 145 may be maintained at about 3° C. to 6° C. or, alternatively 2° C. to 4° C., greater than the desired junction temperature. In one example, the temperature of the upper surface 260 of the platen 145 may be maintained at about 52° C. to 54° C. to provide a desired junction temperature of about 50° C. In another embodiment, a reference cell 420 and/or a dummy PV device may be utilized to provide the desired junction temperature. After the temperature in the processing area 128 has reached a desired set-point, a to-be-tested PV device 255 may be provided in the processing area 128. It is desirable that the lower surface of the PV device 255 be in substantially full contact with the upper surface 260 of the platen 145 to promote thermal conduction between the platen 145 and the PV device 255.

In another embodiment, a to-be-tested PV device 255 is provided to the processing area 128 prior to reaching a steady-state temperature and optical intensity as shown at 810B. In this embodiment, the PV device 255 is supported on the platen 145 to be in intimate contact with the upper surface 260 of the platen 145. The lighting devices 130 are turned on and the master PID controller is set to a ramp-up temperature set-point that is greater than the desired steady-state set point to facilitate a desired junction temperature. The plurality of fan units 125 and/or 240 are controlled by the master PID controller 440 to facilitate the ramp-up temperature set-point. Temperature may be monitored by discrete temperature sensors in or on the platen 145, temperature sensors coupled to or positioned on the PV device 255, and/or the optical sensors 132.

In one example performed by the inventors, the master PID controller 440 was set to about 75° C. to allow the side fan units 125 to remain off during the ramp-up procedure. Discrete temperature sensors such as sensors were positioned on the substrate 302 (FIGS. 3A, 3B) or the upper side 270A of the PV device 255 (FIG. 2E). In this example, twenty five temperature sensors where placed in a grid pattern at a 25 cm spacing. At least two of the temperature sensors were in communication with the controllers 430A, 430B (FIG. 4A) and the master PID controller 440. The processing area 128 reached an initial thermal equilibrium within about 30 minutes with the side fan units 125 and bottom fan units 240 off during this ramp-up procedure.

After the initial thermal equilibrium was reached, the bottom fan units 240 were powered to the lowest speed setting. In this example, the side fan units 125 and bottom fan units 240 were three-speed fans. After about 15 minutes, the temperature in the processing area 128 equilibrated to a secondary thermal equilibrium. Temperatures readings from the discrete temperature sensors were checked and averaged to determine the equilibrated temperature at the surface of the PV device 255. The temperature of the PV device 255 was averaged from 25 points on the PV device 255. In a scenario where the average surface temperature reached a temperature gradient of about 3° C. to 6° C. higher than the desired set-point temperature (e.g., processing temperature), then the bottom fan units 240 were determined to be at the desired speed setting (e.g., lowest speed setting). In a scenario where the average surface temperature was greater than the gradient temperature (e.g., about 3° C. to 6° C. higher than the desired set-point temperature (e.g., processing temperature)), then the bottom fan units 240 were reset to a faster speed until the average temperature was lowered to the desired 3° C. to 6° C. higher than the desired set-point temperature.

After the desired gradient temperature was reached, all eight side fan units 125 were set to the lowest speed. Referring to FIG. 4A, the controllers 430A, 430B were provided with a desired set-point temperature, which in this example was about 50° C. The system was allowed to equilibrate for about 15 minutes after which temperatures from the twenty five sensors were averaged and the standard deviation was calculated. In a scenario where the average measured temperature at this stage differed by more than the standard deviation (calculated at 2° C. in this example), the controllers 430A and 430B were re-calibrated to account for the offset. Zone control of the side fan units 125 as described in FIG. 4A may be utilized to tune temperature uniformity of the PV device 255. For example, if the temperature at the perimeter of the PV device differs significantly than the temperature at the center of the PV device 255, then the set-point temperature may be different for each of the controllers 430A and 430B. In a specific setup example where the desired set point temperature was about 50° C.+/−2° C. (where 2° C. is one standard deviation), the bottom fan units 240 were set at the highest speed while the side fan units 125 were set at the lowest speed. In this example, the controller 430B controlling the first set of fan units 425B at the center was set at 48° C. while the controller 430A controlling the second set of fan units 425A at the edge was set at 50° C. In this example, the PV device 255 was maintained for a period of time at a global temperature of 50° C.

Regardless of the order steps 810A and 810B are performed, the pre-determined set-point temperature is to be maintained for a test period as shown at 820. The test period may vary based on the desires of the user but in one embodiment in an environmental simulation model, the time period is between about 30 minutes to about 300 hours. In one example, the testing period is between about 100 hours to about 300 hours In one embodiment, during or after the environmental simulation model, the electrical characteristics of the PV device 255 may be monitored and evaluated as described in FIG. 4C as shown at 825. In other embodiments, the PV device 255 is removed after environmental simulation process as shown at 830. At 840, the electrical characteristics of the PV device 255 are evaluated in another system.

While the foregoing is directed to embodiments of the invention, other and further embodiments of the invention may be devised without departing from the basic scope thereof.

1. A chamber, comprising:
a frame defining a partial enclosure having an interior volume, the frame comprising a door selectively sealing an opening in the frame;
a plurality of lighting devices coupled to the enclosure interior of an open wall, each of the plurality of lighting devices being positioned to direct light toward an upper surface of a platen disposed in the interior area; and
a plurality of fan units positioned in an opening formed in a sidewall of the frame, each of the plurality of fan units positioned to direct ambient air flow from the outside of the enclosure toward the platen and between the plurality of lighting devices to exit through the open wall.

2. The chamber of claim 1, wherein the plurality of fan units are in communication with a controller.

3. The chamber of claim 2, wherein the plurality of fan units are divided into a first set of fan units that are oriented to direct air flow over a center of the platen and a second set of fan units that are oriented to direct air flow over a perimeter of the platen.

4. The chamber of claim 2, wherein the plurality of fan units are divided into a first set of fan units and a second set of fan units that are in communication with independent controllers.

5. The chamber of claim 1, wherein the plurality of fan units are disposed on opposing sides of the frame.

6. The chamber of claim 1, further comprising:
a plurality of fan units outside of the chamber positioned to direct air flow toward a major surface of the platen.

7. The chamber of claim 1, wherein the platen includes a central opening formed therethrough.

8. The chamber of claim 7, wherein the opening is selectively covered by a removable plate.

9. The chamber of claim 1, wherein the platen is movable into and out of the interior volume.

10. The chamber of claim 9, wherein the platen comprises a plurality of rolling members that are coupled a frame structure.

11. The chamber of claim 9, wherein the platen is coupled to an actuator to provide movement of the platen into and out of the interior volume.

12. An environmental simulator apparatus, comprising:
an enclosure defining a testing region, the enclosure having a plurality of open areas that are in communication with ambient atmosphere;
a plurality of first fan units positioned to direct ambient air flow from outside of the enclosure and across the testing region;
a probe nest positioned to make electrical connection with one or more terminals of a solar module positioned in the testing region; and
a light source configured to emit optical energy simulating the solar spectrum in a direction that is substantially normal relative to an upper surface of the solar module.

13. The apparatus of claim 12, further comprising:
a platen movably disposed in the testing region, the platen having an upper surface adapted to receive the solar module.

14. The apparatus of claim 13, further comprising:
one or more second fan units disposed on an opposing side of the upper surface of the platen and positioned to direct air flow to a major surface of the platen.

15. The apparatus of claim 12, wherein the plurality of first fan units are divided into a first set of fan units and a second set of fan units that are in communication with a first controller and a second controller.

16. The apparatus of claim 15, wherein the first controller and the second controller are in communication with the light source.

17. A method for exposing a solar device to simulated environmental conditions, comprising:
providing a solar device to a chamber, the chamber having an environment that includes a light source simulating the solar spectrum and a first temperature configured to maintain a second temperature in the interior of the solar device that is less than the first temperature; and
maintaining the first temperature during a test period.

18. The method of claim 17, wherein the first temperature is measured on an upper surface of a platen in the chamber.

19. The method of claim 17, wherein the first temperature is measured on an upper surface of the solar device.

20. The method of claim 17, wherein the solar device includes at least one p-i-n junction and the second temperature is maintained at the p-i-n junction.

21. The method of claim 17, wherein the first temperature is provided by the light source.

22. The method of claim 17, wherein the first temperature is provided by a heating device adjacent the solar device.

23. The method of claim 17, wherein the first temperature is regulated by varying the air flow in the chamber.

24. The method of claim 23, wherein the varied air flow is provided by a plurality of fan units.

25. The method of claim 24, wherein the plurality of fan units are coupled to a controller that varies the fan speed based on the first temperature.

26. The method of claim 25, wherein the controller is in communication with the light source.
